(19) United States
(12) Patent Application Publication
(10) Pub. No.: US 2026/0089986 A1
(43) Pub. Date: Mar. 26, 2026

(54) SEMICONDUCTOR DEVICE AND FABRICATING METHOD THEREOF

(71) Applicant: HON HAI PRECISION INDUSTRY CO., LTD., New Taipei City (TW)

(72) Inventors: Jheng-Sheng YOU, Hsinchu City (TW); Han-Chin CHIU, Hsinchu City (TW)

(21) Appl. No.: 18/956,009

(22) Filed: Nov. 22, 2024

(30) Foreign Application Priority Data
Sep. 24, 2024 (TW) 113136072

(51) Int. Cl. H01L 29/94

(52) U.S. Cl. CPC H10D 1/665; H10D 1/043; H10D 1/716

(57) ABSTRACT

A fabricating method of a semiconductor device includes performing a first patterning process to form a first trench in a substrate structure. The substrate structure includes a substrate and a compound semiconductor layer over the substrate. The first patterning process is performed such that the first trench passes through the compound semiconductor layer and exposes the substrate. The fabricating method further includes forming a capacitor structure in the first trench. Forming the capacitor structure includes: forming a first metal layer lining the first trench and in contact with the substrate; forming a first dielectric layer lining the first metal layer and in contact with the first metal layer; and forming a second metal layer lining the first dielectric layer and in contact with the first dielectric layer.

### CROSS-REFERENCE TO RELATED APPLICATION

This application claims priority to Taiwan Application Serial Number 113136072, filed Sep. 24, 2024, which is herein incorporated by reference in its entirety.

### BACKGROUND

### Field of Disclosure

The present disclosure relates to a semiconductor device and a fabricating method of a semiconductor device.

### Description of Related Art

With the development of fabrication technology, semiconductor devices have been miniaturized to increase integration density. However, some issues in fabricating the semiconductor devices may arise from the scaling down process. For example, as critical dimensions shrink, electrode surface areas of capacitors decrease, resulting in the reduction of capacitances. Accordingly, how to improve the capacitance density of the semiconductor devices becomes an important issue to be solved by those in the industry.

### SUMMARY

An aspect of the disclosure is to provide a semiconductor device and a fabricating method of a semiconductor device that may efficiently solve the aforementioned problems.

According to some embodiments of the present disclosure, a fabricating method of a semiconductor device includes performing a first patterning process to form a first trench in a substrate structure. The substrate structure includes a substrate and a compound semiconductor layer over the substrate. The first patterning process is performed such that the first trench passes through the compound semiconductor layer and exposes the substrate. The fabricating method further includes forming a capacitor structure in the first trench. Forming the capacitor structure includes: forming a first metal layer lining the first trench and in contact with the substrate; forming a first dielectric layer lining the first metal layer and in contact with the first metal layer; and forming a second metal layer lining the first dielectric layer and in contact with the first dielectric layer.

According to some other embodiments of the present disclosure, a semiconductor device includes a substrate structure and a capacitor structure. The substrate structure includes a substrate and a compound semiconductor layer over the substrate. The capacitor structure is over the substrate structure and includes a first metal layer, a first dielectric layer, and a second metal layer. The first metal layer has a first portion extending downward through the compound semiconductor layer and in contact with the substrate. The first dielectric layer is over the first metal layer and lining the first portion of the first metal layer. The second metal layer is over the first portion of the first metal layer, over the first dielectric layer, and lining the first dielectric layer.

### BRIEF DESCRIPTION OF THE DRAWINGS

The disclosure can be more fully understood by reading the following detailed description of the embodiment, with reference made to the accompanying drawings as follows:

FIG. 1 to FIG. 4 are partial cross-sectional views of intermediate stages of a fabricating method of a semiconductor device according to some embodiments of the present disclosure;

FIG. 5 is a top view of an intermediate stage of a fabricating method of a semiconductor device according to some embodiments of the present disclosure;

FIG. 6 is a partial cross-sectional view of a semiconductor device according to some other embodiments of the present disclosure; and

FIG. 7 is a partial cross-sectional view of a semiconductor device according to still some other embodiments of the present disclosure.

### DETAILED DESCRIPTION

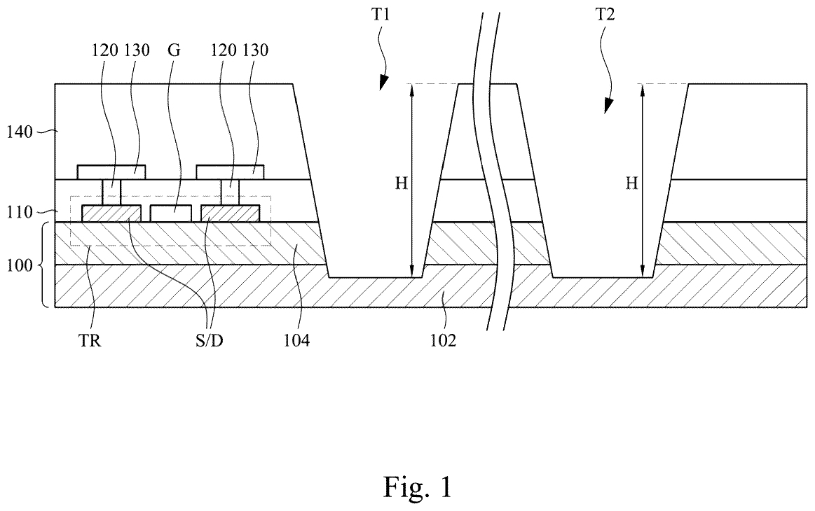

FIG. 1 to FIG. 4 are partial cross-sectional views of intermediate stages of a fabricating method of a semiconductor device according to some embodiments of the present disclosure, respectively.

First, reference is made to FIG. 1. A substrate structure 100 is provided. As shown in FIG. 1, the substrate structure 100 includes a substrate 102 and a compound semiconductor layer 104 over the substrate 102. The substrate 102 may include a silicon (Si) substrate, a silicon carbide (SiC) substrate, a gallium nitride (GaN) substrate, an aluminum gallium nitride (AlGaN) substrate, or an aluminum nitride (AlN) substrate. The compound semiconductor layer 104 may include a III-V compound semiconductor. To be more specific, the compound semiconductor layer 104 may include gallium nitride, aluminum gallium nitride, aluminum nitride, or combinations thereof. For example, the compound semiconductor layer 104 may include a gallium nitride layer and an aluminum gallium nitride layer on the gallium nitride layer, in which the gallium nitride layer may include a channel region that allows two-dimensional electron gas (2DEG) to pass through. In some embodiments, the substrate structure 100 may have active devices such as the transistor TR in FIG. 1. The transistor TR has a gate contact G and a plurality of source/drain contacts S/D disposed on both sides of the gate contact G on a top surface of the compound semiconductor layer 104. The transistor TR may be a high electron mobility transistor (HEMT). However, this disclosure is not limited thereto.

As shown in FIG. 1, a metal interconnect structure and a plurality of dielectric layers are disposed over the substrate structure 100. To be more specific, a dielectric layer 110 is over the substrate structure 100 and covers the transistor TR and the top surface of the compound semiconductor layer 104. The metal interconnect structure may include a plurality of through vias 120 and a metal layer 130. The through vias 120 pass through the dielectric layer 110 to be in contact with the source/drain contacts S/D of the transistor TR and electrically connected to the source/drain contacts S/D. The metal layer 130 is over the dielectric layer 110 and connected to the through vias 120. The metal layer 130 may be referred to as a first metal line (M1) of the metal interconnect structure. A dielectric layer 140 is over the dielectric layer 110 and covers top surfaces of the metal layer 130 and the dielectric layer 110. The metal interconnect structure may further include other metal lines and through vias connected to the metal layer 130 and disposed in the dielectric layer 140. The dielectric layer 140 may be a stack of dielectric layers formed through a series of processes. However, this disclosure is not limited thereto.

Then, a first patterning process is performed to the aforementioned intermediate structure to form a trench T1 and a trench T2 in the substrate structure 100. As shown in FIG. 1, the trench T1 and the trench T2 are disposed at one side of the transistor TR. The trench T1 and the trench T2 pass through the dielectric layer 140, the dielectric layer 110, and the compound semiconductor layer 104 and expose a portion of the substrate 102. In some embodiments, bottom surfaces of the trench T1 and the trench T2 may be lower than a top surface of the substrate 102. Heights H of the trench T1 and the trench T2 may be between about 5 microns and about 30 microns. For example, the heights H of the trench T1 and the trench T2 may be about 15 microns.

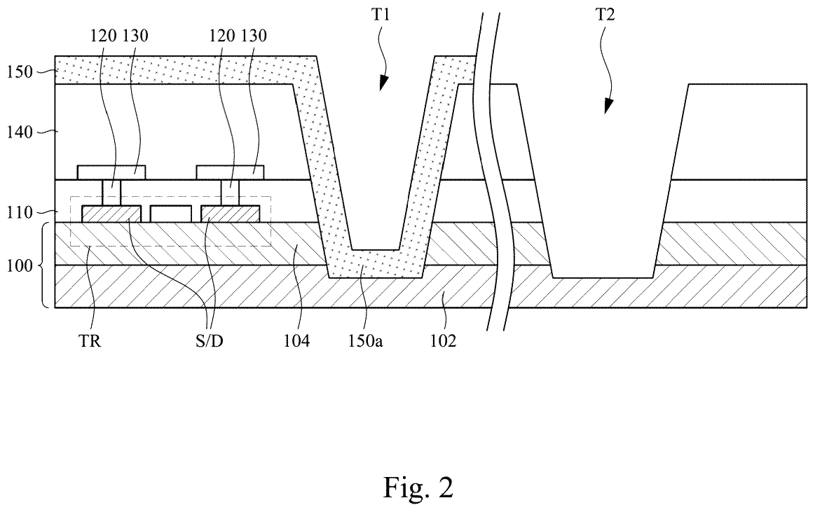

Next, reference is made to FIG. 2. A metal layer 150 is formed lining a top surface of the dielectric layer 140 and lining the trench T1 and the trench T2. The metal layer 150 extends from over the transistor TR along sidewalls of the trench T1 downward through the dielectric layer 140, the dielectric layer 110, and the compound semiconductor layer 104 to be in contact with the substrate 102. In some embodiments, a bottom surface of a horizontal portion 150a of the metal layer 150 that is in contact with the substrate 102 may be lower than the top surface of the substrate 102. A top surface of the horizontal portion 150a of the metal layer 150 may be lower than the top surface of the compound semiconductor layer 104. Similarly, the metal layer 150 may extend from the top surface of the dielectric layer 140 downward along sidewalls of the trench T2 to be in contact with the substrate 102.

In some embodiments, after the metal layer 150 is formed, a second patterning process is performed to pattern the metal layer 150. After the second patterning process, a portion of the metal layer 150 that is formed in the trench T2 is removed and the portion of the substrate 102 is re-exposed. In some embodiments, some other portions of the metal layer 150 that are adjacent to the trench T2 and over the dielectric layer 140 are removed as well through the second patterning process. The intermediate structure after the second patterning process is as shown in FIG. 2. The patterned metal layer 150 serves as a top metal line of the metal interconnect structure.

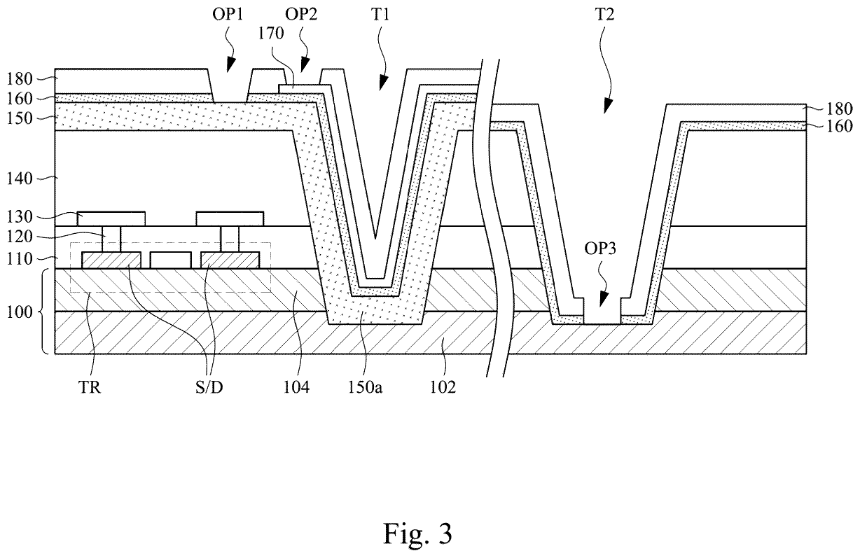

Reference is then made to FIG. 3. A dielectric layer 160 is formed over the metal layer 150 and lining the metal layer 150. The dielectric layer 160 extends from over the transistor TR along the metal layer 150 into the trench T1. The dielectric layer 160 is partially lower than the top surface of compound semiconductor layer 104. In some embodiments, the dielectric layer 160 is formed lining the trench T2. As shown in FIG. 3, the dielectric layer 160 extends from the top surface of the dielectric layer 140 into the trench T2 and is in contact with the exposed portion of the substrate 102 at the bottom of the trench T2. A bottom surface of a portion of the dielectric layer 160 that is in contact with the substrate 102 may be lower than the top surface of the substrate 102. On the other hand, a top surface of the portion of the dielectric layer 160 that is in contact with the substrate 102 may be lower than the top surface of the compound semiconductor layer 104.

Next, a metal layer 170 is formed lining the dielectric layer 160. The metal layer 170 extends along the dielectric layer 160 into the trench T1. The metal layer 170 may be partially lower than the top surface of the compound semiconductor layer 104.

In some embodiments, after the metal layer 170 is formed, a third patterning process is performed to pattern the metal layer 170. The third patterning process is performed such that a portion of the metal layer 170 that is formed in the trench T2 is removed and the dielectric layer 160 formed in the trench T2 is exposed. In some embodiments, some other portions of the metal layer 170 that are adjacent to the trench T2 and over the dielectric layer 140 are also removed through the third patterning process. The resultant structure is as shown in FIG. 3.

Then, a dielectric layer 180 is formed covering the dielectric layer 160 and the metal layer 170. The dielectric layer 180 is partially in contact with the dielectric layer 160. Next, the dielectric layer 180 is patterned to form an opening OP1, an opening OP2, and an opening OP3. The opening OP1 and the opening OP2 expose top surfaces of the metal layer 150 and the metal layer 170, respectively. The opening OP3 is at the bottom of the trench T2 and exposes the substrate 102.

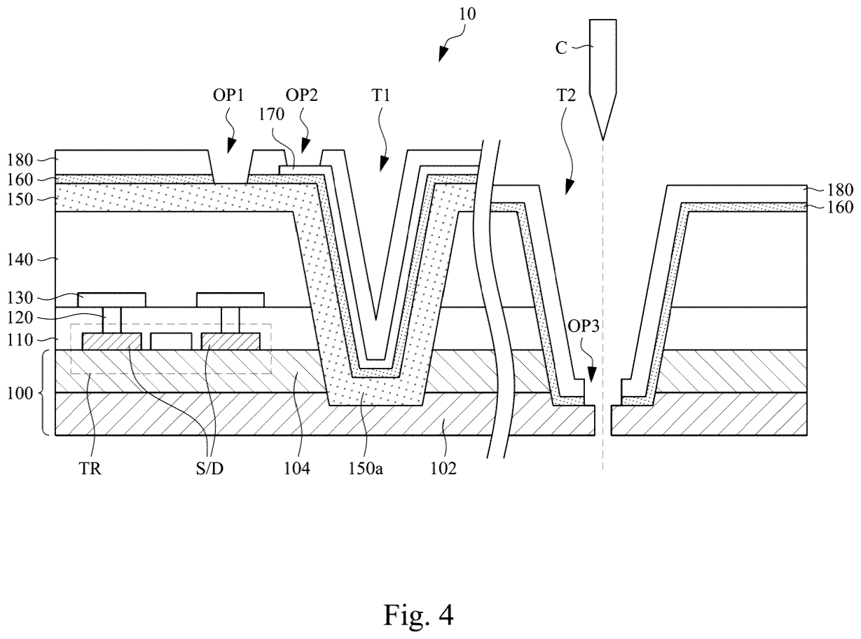

Next, reference is made to FIG. 4. The trench T2 is used as a scribe line so that dies including semiconductor devices can be scribed and separated through the trench T2. For example, a cutting tool C is used to perform a scribing process through the opening OP3 at the bottom of the trench T2 so that the processed substrate structure can be diced into multiple dies. In some other embodiments, the scribing process can be performed by laser or plasma etching.

After the scribing process is completed, the semiconductor device 10 is formed. As shown in FIG. 4, the semiconductor device 10 includes a substrate structure 100, a metal interconnect structure over the substrate structure 100, and a plurality of dielectric layers. The substrate structure 100 includes a substrate 102 and a compound semiconductor layer 104 over the substrate 102. The metal interconnect structure includes a plurality of through vias 120, a metal layer 130, and a metal layer 150. The metal layer 130 serves as a first metal line of the metal interconnect structure. The metal layer 150 serves as a top metal line of the metal interconnect structure. The structural features of each layer are the same as described above and will not be repeated here.

As shown in FIG. 4, the semiconductor device 10 further includes a dielectric layer 160, a metal layer 170, and a dielectric layer 180 over the metal interconnect structure. The dielectric layer 160 is over the metal layer 150, lining the metal layer 150, and in contact with the metal layer 150. The metal layer 170 is lining the dielectric layer 160 and is in contact with the dielectric layer 160. The dielectric layer 180 is over the metal layer 170 and has an opening OP1 and an opening OP2 exposing the top surfaces of the metal layer 150 and the metal layer 170, respectively.

Under such configuration, the metal layer 150, the dielectric layer 160, and the metal layer 170 of the metal interconnect structure can form a deep trench metal-insulator-metal (MIM) capacitor in the trench T1. The metal layer 150 serves as a bottom electrode. The metal layer 170 serves as a top electrode. The bottom electrode and the top electrode are electrically insulated through the dielectric layer 160. By forming the deep trench capacitor, the contact areas among the bottom electrode, the top electrode, and the dielectric layer 160 can be increased to increase the capacitance and the capacitance density. In some embodiments, the metal layer 150 and the metal layer 170 may include a conductive material, such as titanium nitride (TiN), aluminum, copper, or any suitable conductive material. The dielectric layer 160 may include a high-k material, such as silicon oxide (SiO₂), hafnium oxide (HfO₂), titanium oxide (TiO₂), tantalum oxide (Ta₂O₃), zirconium oxide (ZrO₂), aluminum oxide (Al₂O₃), or any suitable dielectric material.

Through the fabricating method of the semiconductor device of the present disclosure, the trench T1 for forming the deep trench capacitor and the trench T2 (or a similar through via passing through the compound semiconductor layer 104) for the scribing process can be formed at the same time during the back-end process. In other words, the trench T1 and the trench T2 are formed simultaneously through a same photomask. In addition, the top metal line of the metal interconnect structure can be used as the bottom electrode of the deep trench capacitor. As a result, the fabricating method of some embodiments of the present disclosure can simplify the fabrication process and improve process efficiency. Otherwise, in currently common processes, two additional photomasks are required for forming the trench T1 and patterning the bottom electrode metal layer after the metal interconnect structure and the trench T2 are formed.

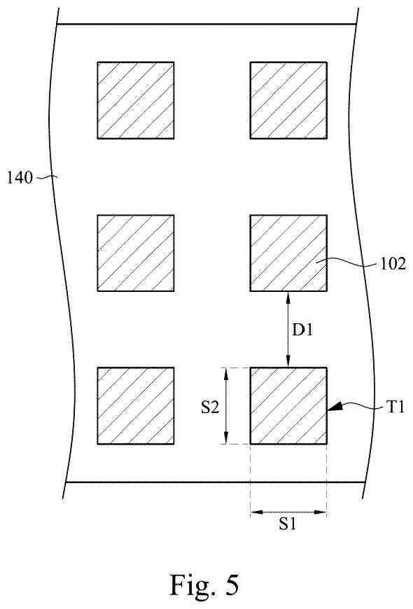

Reference is made to FIG. 5. FIG. 5 is a partial top view of an intermediate stage of a fabricating method of a semiconductor device according to some embodiments of the present disclosure. After performing the first patterning process, the formed trenches are distributed as shown in FIG. 5. In some embodiments, contours of the trenches in the top view may be rectangular. For example, the contour of the trench T1 in the top view is a rectangle. A side length S1 and a side length S2 of the trench T1 can be about 10 microns, respectively. The distance D1 between the trench T1 and an adjacent trench can be about 10 microns. In cases where the height of the trench T1 is about 15 microns and a thickness of the dielectric layer 160 is about 600 Å, the deep trench MIM capacitor formed with the metal layer 150, the dielectric layer 160, and the metal layer 170 may have a capacitance density of about 1.44 fF/μm², which is 2.5 times a capacitance density of a planar MIM capacitor. In some embodiments, side lengths of the trench T2 (not shown in FIG. 5) may be different from the side length S1 and the side length S2 of the trench T1. For example, the side lengths of the trench T2 may be between about 70 microns and about 100 microns. In some embodiments, the contours of the trenches in the top view may be circular, elliptical, hexagonal, or polygonal, but the present disclosure is not limited thereto.

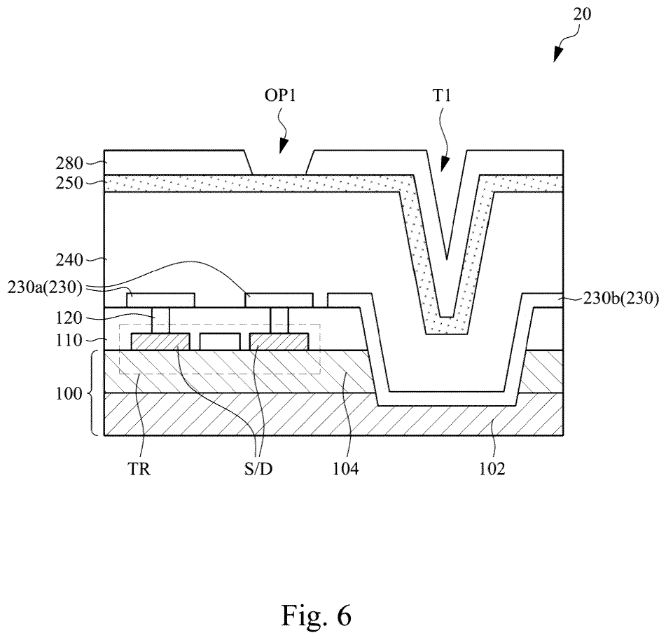

In some embodiments, other metal lines of the metal interconnect structure may be used as the bottom electrode and/or the top electrode of the deep trench capacitor. For example, reference is made to FIG. 6. FIG. 6 is a partial cross-sectional view of a semiconductor device 20 according to some other embodiments of the present disclosure. The difference between the semiconductor device 20 and the semiconductor device 10 is that the first metal line of the metal interconnect structure of the semiconductor device 20 acts as the bottom electrode of the deep trench capacitor and the top metal line of the metal interconnect structure of the semiconductor device 20 acts as the top electrode of the deep trench capacitor. To be more specific, the first metal line of the semiconductor device 20 is the metal layer 230 shown in FIG. 6. The top metal line of the semiconductor device 20 is the metal layer 250 shown in FIG. 6. The metal layer 230 has a portion 230a and a portion 230b. The portion 230a is over the dielectric layer 110 and connected to the through vias 120. The portion 230b is at one side of the transistor TR and extends from over the dielectric layer 110 downward through the dielectric layer 110 and the compound semiconductor layer 104 and is in contact with the substrate 102. The dielectric layer 240 covers the metal layer 230 and is lining the portion 230b. The metal layer 250 is lining the dielectric layer 240. In this way, the portion 230b of the metal layer 230, the dielectric layer 240, and the metal layer 250 form a deep trench capacitor. It should be noted that a bottom surface of the portion 230b of the metal layer 230 that is in contact with the substrate 102 may be lower than the top surface of the substrate 102. The metal layer 250 may be completely higher than the top surface of the compound semiconductor layer 104. In addition, the dielectric layer 280 covers the metal layer 250 and has an opening OP1 that exposes a portion of the metal layer 250.

In the fabricating method of the semiconductor device 20, before forming the metal layer 230, a first patterning process is performed to form a trench (corresponding to the trench T1 of the semiconductor device 10) passing through the dielectric layer 110 and the compound semiconductor layer 104, thereby exposing the substrate 102. Next, the metal layer 230 is formed over the dielectric layer 110 and extends into the trench, so that the portion 230a of the metal layer 230 is connected to the through vias 120, and the portion 230b of the metal layer 230 is lining the trench and in contact with the substrate 102. Next, the dielectric layer 240, the metal layer 250, and the dielectric layer 280 lining the metal layer 230 are formed sequentially. In some embodiments, the first patterning process may be performed to form a trench (corresponding to the trench T2 of the semiconductor device 10) used as a scribe line simultaneously.

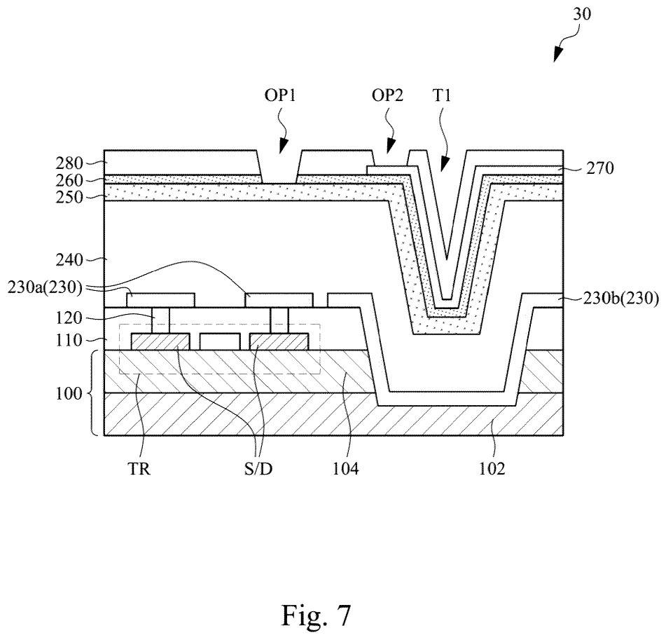

Reference is made to FIG. 7. FIG. 7 is a partial cross-sectional view of a semiconductor device 30 according to still some other embodiments of the present disclosure. The difference between the semiconductor device 30 and the semiconductor device 20 is that the semiconductor device 30 further includes a dielectric layer 260 and a metal layer 270. The dielectric layer 260 is over the metal layer 250 and lining the metal layer 250. The metal layer 270 is over the dielectric layer 260 and lining the dielectric layer 260. The dielectric layer 280 is over the metal layer 270 and has an opening OP1 and an opening OP2 that expose the metal layer 250 and the metal layer 270, respectively. In this way, the portion 230a of the metal layer 230, the dielectric layer 240, the metal layer 250, the dielectric layer 260, and the metal layer 270 form a deep trench capacitor to further increase the capacitance density. In addition, as shown in FIG. 7, the metal layer 250, the dielectric layer 260, and the metal layer 270 may be completely higher than the top surface of the compound semiconductor layer 104. The fabricating method of the semiconductor device 30 further includes forming the dielectric layer 260 over the transistor TR and the trench and lining the metal layer 250, forming the metal layer 270 over the trench and lining the dielectric layer 260, and forming the dielectric layer 280 covering the dielectric layer 260 and the metal layer 270 and has the opening OP1 and the opening OP2.

According to the foregoing recitations of the embodiments of the disclosure, it may be seen that in the semiconductor device and the fabricating method of the semiconductor device of some embodiments of the present disclosure, the trench for forming the deep trench capacitor and the trench of the scribe line can be formed at the same time. Therefore, the capacitance and the capacitance density are increased. In addition, the metal lines of the metal interconnect structure are used as the bottom electrode and/or the top electrode of the deep trench capacitor. As such, compared with currently common fabrication processes, photomasks for forming the deep trenches and the electrodes of the deep trench capacitor may be omitted in the fabricating method of the present disclosure, further simplifying the fabrication process and improving process efficiency.

What is claimed is:

1. A fabricating method of a semiconductor device, comprising:
performing a first patterning process to form a first trench in a substrate structure, wherein the substrate structure comprises a substrate and a compound semiconductor layer over the substrate, and the first trench passes through the compound semiconductor layer and exposes the substrate; and
forming a capacitor structure in the first trench, wherein forming the capacitor structure comprises:
forming a first metal layer lining the first trench and in contact with the substrate;
forming a first dielectric layer lining the first metal layer and in contact with the first metal layer; and
forming a second metal layer lining the first dielectric layer and in contact with the first dielectric layer.

2. The fabricating method of claim 1, wherein the substrate structure comprises a transistor and the first metal layer is formed such that the first metal layer extends from over the transistor along the first trench to a side of the transistor.

3. The fabricating method of claim 2, wherein the first metal layer is formed such that a first portion of the first metal layer is at the side of the transistor and in contact with the substrate, and a top surface of the first portion of the first metal layer is lower than a top surface of the compound semiconductor layer.

4. The fabricating method of claim 3, wherein the first metal layer is formed such that a bottom surface of the first portion of the first metal layer is lower than a top surface of the substrate.

5. The fabricating method of claim 3, wherein the first dielectric layer is formed such that the first dielectric layer is partially lower than the top surface of the compound semiconductor layer.

6. The fabricating method of claim 2, wherein the first metal layer is formed such that a second portion of the first metal layer is electrically connected to a source/drain contact of the transistor through a through via.

7. The fabricating method of claim 6, wherein the second metal layer is completely higher than a top surface of the compound semiconductor layer.

8. The fabricating method of claim 6, wherein forming the capacitor structure further comprises:
forming a second dielectric layer lining the second metal layer and in contact with the second metal layer; and
forming a third metal layer lining the second dielectric layer and in contact with the second dielectric layer.

9. The fabricating method of claim 1, wherein the second metal layer is partially lower than a top surface of the compound semiconductor layer.

10. The fabricating method of claim 1, wherein:
performing the first patterning process further comprises forming a second trench in the substrate structure and exposing the substrate;
forming the capacitor structure further comprises:
forming the first metal layer such that the first metal layer is lining the second trench; and
after the first metal layer is formed, performing a second patterning process to the first metal layer to remove a portion of the first metal layer that is in the second trench to re-expose the substrate through the second trench; and
the fabricating method further comprises performing a scribing process through the second trench.

11. A semiconductor device, comprising:
a substrate structure comprising a substrate and a compound semiconductor layer over the substrate; and
a capacitor structure over the substrate structure and comprising:
a first metal layer having a first portion extending downward through the compound semiconductor layer and in contact with the substrate;
a first dielectric layer over the first metal layer and lining the first portion of the first metal layer; and
a second metal layer over the first portion of the first metal layer, over the first dielectric layer, and lining the first dielectric layer.

12. The semiconductor device of claim 11, further comprising a second dielectric layer and a third metal layer, wherein the second dielectric layer is over the second metal layer and lining the second metal layer, and the third metal layer is over the second dielectric layer and lining the second dielectric layer.

13. The semiconductor device of claim 12, wherein the second metal layer, the second dielectric layer, and the third metal layer are completely higher than a top surface of the compound semiconductor layer.

14. The semiconductor device of claim 11, wherein a bottom surface of the first portion of the first metal layer is lower than a top surface of the substrate.

15. The semiconductor device of claim 11, wherein a top surface of the first portion of the first metal layer is lower than a top surface of the compound semiconductor layer.

16. The semiconductor device of claim 11, wherein the first dielectric layer is partially lower than a top surface of the compound semiconductor layer.

17. The semiconductor device of claim 11, wherein the second metal layer is completely higher than a top surface of the compound semiconductor layer.

18. The semiconductor device of claim 11, wherein the second metal layer is partially lower than a top surface of the compound semiconductor layer.

19. The semiconductor device of claim 11, wherein the substrate structure comprises a transistor and a second portion of the first metal layer is over the transistor and is electrically connected to a source/drain contact of the transistor through a through via.

20. The semiconductor device of claim 19, wherein the first portion of the first metal layer is at a side of the transistor.
